(19) United States
(12) Patent Application Publication
(10) Pub. No.: US 2026/0135466 A1
(43) Pub. Date: May 14, 2026

(54) INVERTER DRIVING APPARATUS, INVERTER CONTROLLING METHOD THEREOF, AND VEHICLE COMPRISING THE SAME

(71) Applicants: HYUNDAI MOTOR COMPANY, SEOUL (KR); KIA CORPORATION, SEOUL (KR)

(72) Inventors: Tae Jun Moon, Hwaseong-si (KR); Ho Rim Choi, Hwaseong-si (KR); Jin Wook Kang, Hwaseong-si (KR); Tae Gyeom Woo, Hwaseong-si (KR); Tae Il Yoo, Hwaseong-si (KR); Sang Woo Park, Hwaseong-si (KR)

(73) Assignees: HYUNDAI MOTOR COMPANY, SEOUL (KR); KIA CORPORATION, SEOUL (KR)

(21) Appl. No.: 19/225,794

(22) Filed: Jun. 2, 2025

(30) Foreign Application Priority Data
Nov. 13, 2024 (KR) 10-2024-0160663

(51) Int. Cl. H02M 1/08; H02M 7/537; H03K 3/017

(52) U.S. Cl. CPC H02M 1/08; H02M 7/537; H03K 3/017

(57) ABSTRACT

An inverter driving apparatus is capable of resolving the current imbalance among power modules having different threshold voltages in an inverter including a plurality of power modules connected in parallel. The inverter driving apparatus drives an inverter including a plurality of power modules connected in parallel and includes a gate driver outputting control signals to the plurality of power modules and monitoring threshold voltage of the plurality of power modules, and a controller controlling the gate driver in response to an instruction input from outside. The controller may change a preset first PWM signal to generate a second PWM signal based on the threshold voltage for the plurality of power modules provided by the gate driver and output the second PWM signal to the gate driver.

### CROSS REFERENCE TO RELATED APPLICATIONS

The present application claims the benefit of priority under 35 U.S.C. 119 to Korean Patent Application No. 10-2024-0160663, filed Nov. 13, 2024, in the Korean Intellectual Property Office, the entire contents of which is incorporated herein for all purposes by this reference.

### TECHNICAL FIELD

The present disclosure is related to inverter control, and more particularly, to an inverter driving apparatus, an inverter controlling method thereof, and a vehicle including the same, wherein the inverter driving apparatus may resolve the current imbalance among power modules having different threshold voltages in an inverter that includes a plurality of power modules connected in parallel.

### BACKGROUND

An inverter implemented in vehicles may be used for converting a direct current voltage from a high-voltage battery into an alternating current voltage to drive a motor. The inverter may include a plurality of power modules connected in parallel and operate based on a control signal (or control voltage) output by a gate driver.

The gate driver may output a control signal to a gate terminal of the plurality of power modules in response to a pulse width modulation (PWM) signal provided by a controller, and the plurality of power modules may be turned on or off in response to the control signal from the gate driver.

In the structure of an inverter having a plurality of power modules connected in parallel, the current imbalance may cause burnout of the power modules.

While the current imbalance can be adequately addressed during the design phase and rectified after identification, it is difficult to identify and manage the current imbalance stemming from threshold voltage variations of power modules.

Therefore, a solution is needed to address the current imbalance problem stemming from threshold voltage variations of power modules.

The matters described above as background technology are intended to facilitate a better understanding of the background of the present disclosure and are not to be taken as an admission that the present disclosure pertains to the conventional technology already known to those skilled in the art.

### SUMMARY

Embodiments disclosed in the present disclosure are proposed in response to the needs described above, and a technical objective is to provide an inverter driving apparatus, an inverter controlling method thereof, and a vehicle including the same, wherein the inverter driving apparatus may resolve the current imbalance among power modules having different threshold voltages in an inverter that includes a plurality of power modules connected in parallel.

The objective of the embodiments of the present disclosure is to provide an inverter driving apparatus, an inverter controlling method thereof, and a vehicle including a vehicle, wherein the inverter driving apparatus may ensure that the current of power modules having different threshold voltages is output simultaneously at a preset time by changing the generation point of a PWM signal or changing the duty of the PWM signal based on a delay determined based on the threshold voltage of each power module and controlling the power modules based on the changed PWM signal.

The technical issues to be resolved by the present disclosure are not limited to the technical issues mentioned above, and other unmentioned technical issues will be clearly understood by those skilled in the art to which the present disclosure pertains from the following description.

An inverter driving apparatus according to an embodiment of the present disclosure for achieving the objective described above may drive an inverter including a plurality of power modules connected in parallel and include a gate driver outputting a control signal to the plurality of power modules and monitoring the threshold voltage of the plurality of power modules and a controller controlling the gate driver in response to an instruction input from outside, wherein the controller may change a first PWM signal generated in response to an instruction to generate a second PWM signal based on the threshold voltage for the plurality of power modules provided by the gate driver and output the second PWM signal to the gate driver.

According to an embodiment of the present disclosure, the controller may change the generation point of the first PWM signal or change the duty of the first PWM signal to generate the second PWM signal based on the delay determined based on the threshold voltage.

According to an embodiment of the present disclosure, the controller may apply the aforementioned delay to the count serving as a reference for the generation point of the first PWM signal to generate the second PWM signal and the second PWM signal may be generated with a delay equal to the aforementioned delay, relative to the first PWM signal.

According to an embodiment of the present disclosure, the controller may apply the aforementioned delay to at least one of a turn-on point and a turn-off point of the first PWM signal to generate the second PWM signal having a longer duty than the first PWM signal.

According to an embodiment of the present disclosure, the controller may apply the aforementioned delay to the turn-on point and turn-off point of the first PWM signal. The turn-on point of the second PWM signal may be delayed relative to the turn-on point of the first PWM signal by the aforementioned delay, and the turn-off point of the second PWM signal may be delayed relative to the turn-off point of the first PWM signal by the aforementioned delay.

According to an embodiment of the present disclosure, the controller may apply the aforementioned delay to the turn-on point of the first PWM signal and the turn-on point of the second PWM signal may be delayed relative to the turn-on point of the first PWM signal by the aforementioned delay.

According to an embodiment of the present disclosure, the controller may determine the aforementioned delay based on the slope characteristics of the gate-source voltage of the power module.

According to an embodiment of the present disclosure, the controller may determine the aforementioned delay based on the following mathematical formula 1:

$$delay = \frac{Vth 1 - Vth 2}{dVgs / dt} ( Vth 1 > Vth 2 ) , \qquad Mathematical formula 1$$

where Vth1 is the threshold voltage of the first power module, Vth2 is the threshold voltage of the second power module, and dVgs/dt is the current flowing through the gate resistor Rg.

According to an embodiment of the present disclosure, the controller may determine the aforementioned delay corresponding to the threshold voltage based on a table including delays for each threshold voltage.

According to an embodiment of the present disclosure, the gate driver may include a threshold voltage monitoring circuit monitoring the threshold voltage of the plurality of power modules, converting the monitored threshold voltage into a digital signal, and providing the digital signal to the controller.

According to an embodiment of the present disclosure, the inverter may include a plurality of module groups that include a plurality of power modules connected in parallel, a gate driver may be connected to each of the plurality of gate module groups, and each of the plurality of gate drivers may monitor the threshold voltage for the plurality of power modules in the connected module group.

According to an embodiment of the present disclosure, the gate driver may monitor the voltage of the gate resistor connected between the gate driver and the gate terminal of the power module in a state where a switching element connected between the gate terminal and a drain terminal of the power module is short-circuited.

An inverter controlling method according to an embodiment of the present disclosure may be a method of controlling an inverter including a plurality of power modules connected in parallel and include generating, by a controller, a first PWM signal in response to an instruction input from outside to output the first PWM signal to a gate driver, monitoring, by the gate driver, a threshold voltage of a plurality of power modules, providing, by the gate driver, the monitored threshold voltage to the controller, and changing, by the controller, the first PWM signal to generate a second PWM signal based on the threshold voltage and outputting the second PWM signal to the gate driver.

A vehicle according to an embodiment of the present disclosure may include an inverter that includes a plurality of power modules connected in parallel and an inverter driving apparatus controlling the inverter, wherein the inverter driving apparatus may include a gate driver outputting a control signal to the plurality of power modules and monitoring threshold voltage of the plurality of power modules and a controller controlling the gate driver in response to an instruction input from outside, and the controller may change a first PWM signal generated in response to the instruction to generate a second PWM signal based on the threshold voltage for the plurality of power modules provided by the gate driver and output the second PWM signal to the gate driver.

Specific details according to various embodiments of the present disclosure, other than the solutions to the problems mentioned above, are included in the following description and drawings.

According to an embodiment of the present disclosure, an inverter driving apparatus, an inverter controlling method thereof, and a vehicle including the same may be provided, wherein the inverter driving apparatus may resolve the current imbalance among power modules having different threshold voltages in an inverter that includes a plurality of power modules connected in parallel.

According to an embodiment of the present disclosure, an inverter driving apparatus an inverter controlling method thereof, and a vehicle including the same may be provided, wherein the inverter driving apparatus may simultaneously output the current of power modules having different threshold voltages at a preset time by changing the generation point of the PWM signal or changing the duty of the PWM signal based on delay determined based on the threshold voltage of each power module and controlling the power modules based on the changed PWM signal.

According to an embodiment of the present disclosure, the controller generates a PWM signal in consideration of the variations of the threshold voltage of the plurality of power modules connected in parallel, so that the current imbalance problem among the power modules that may stem from the threshold voltage variations of the power modules connected in parallel may be ameliorated.

When the current imbalance problem among the power modules is ameliorated, the efficiency of inverter control may be enhanced and the stability of the inverter may be improved through reduced current peaks and optimized gate resistance.

When the inverter driving apparatus and the inverter controlling method according to embodiments of the present disclosure are applied to a vehicle, the device (e.g. motor) driven by the inverter may be stably driven and the vehicle performance may be improved.

The effects obtainable from the present disclosure are not limited to the effects mentioned above, and other unmentioned effects will be clearly understood by those skilled in the art to which the present disclosure pertains from the following description.

### BRIEF DESCRIPTION OF THE FIGURES

The accompanying drawings are intended to facilitate a better understanding of the embodiments in the present disclosure, and the embodiments are provided along with detailed descriptions. However, a specific drawing does not limit the technical features of the embodiments, and the features disclosed in each drawing may be combined to form new embodiments.

FIG. 1 is a view illustrating a configuration of an inverter driving system including an inverter driving apparatus according to an embodiment of the present disclosure.

FIG. 2 is a view for describing a method of monitoring threshold voltage Vth in an embodiment of the present disclosure.

FIG. 3 is a view for describing a method by which a controller changes PWM signals by a controller in an embodiment of the present disclosure.

FIG. 4 is a view illustrating a gate-source voltage Vgs_1 in response to a PWM signal input into a power module.

FIG. 5 is a view illustrating a current Id_1 flowing through a power module in response to the gate-source voltage in FIG. 4.

FIG. 6 is a view illustrating a gate-source voltage Vgs_2 when the PWM signal applied in FIGS. 4 and 5 is changed according to a first embodiment and input into a power module.

FIG. 7 is a view illustrating a current Id_2 flowing through a power module in response to the gate-source voltage Vgs_2 in FIG. 6.

### DETAILED DESCRIPTION

In describing the embodiments set forth herein, a detailed description of known functions or configurations incorporated herein will be omitted when it is determined that the description may make the subject matter of the embodiments set forth herein unclear. Further, it is to be understood that the accompanying drawings are only intended to facilitate understanding of the embodiments disclosed herein and are not intended to limit the technical ideas disclosed herein are not limited to the accompanying drawings and include all the modifications, equivalents, or substitutions within the spirit and technical scope of the present disclosure.

The terms including ordinal numbers such as first, second, and the like may be used to describe various components, but the components are not to be limited by the terms. The terms may only be used to distinguish one component from another.

Singular expressions include plural expressions unless the context explicitly indicates otherwise.

In the present specification, terms such as “comprise” or “have” are intended to indicate the presence of implemented features, numbers, steps, manipulations, components, parts, or combinations thereof described in the specification and are not to be understood to preclude the presence or additional possibilities of one or more of other features, numbers, steps, manipulations, components, parts or combinations thereof.

The suffixes “module” and “unit” used for components in the following description are assigned or used interchangeably only in consideration of facilitating the preparation of the specification and are not intended to have distinct meanings or roles in and of themselves.

It is to be understood that when one component is referred to as being “connected” or “linked” to another component, the component may be directly connected or linked but there may be other components in between. In contrast, when one component is referred to as being “directly connected” or “directly linked” to another component, it is to be understood that there is no other component in between.

Hereinafter, embodiments disclosed in the present specification will be described in detail with reference to the accompanying drawings. Identical or similar components are assigned the same reference numerals regardless of drawing designation, and repetitive descriptions thereof will be omitted.

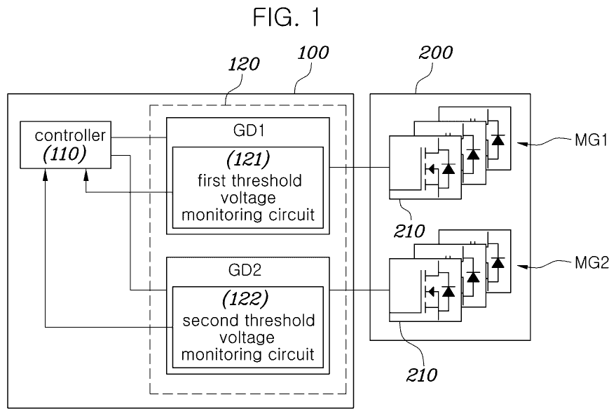

FIG. 1 is a view illustrating a configuration of an inverter driving system including an inverter driving apparatus 100 according to an embodiment of the present disclosure.

FIG. 1 shows that an inverter driving apparatus 100 may be implemented to control an inverter 200. According to an embodiment, the inverter 200 may include a plurality of power modules 210 connected in parallel.

For example, the power module 210 may be a switching element implemented as an insulated gate bipolar transistor (IGBT).

For example, the inverter 200 may include a first module group MG1 including a plurality of power modules 210 connected in parallel and a second module group MG2 including a plurality of power modules 210 connected in parallel. However, the structure of the inverter 200 is not limited thereto.

For example, the inverter driving apparatus 100 and the inverter 200 according to an embodiment of the present disclosure may be implemented in a vehicle and the inverter 200 may be implemented to control the drive motor of the vehicle. Of course, the application of the inverter driving apparatus 100 and the inverter 200 according to the embodiment of the present disclosure is not limited to vehicles.

According to an embodiment, the inverter driving apparatus 100 may include a controller 110 and a gate driver 120.

The controller 110 may receive an instruction output by a higher-level control unit and generate a PWM signal corresponding to the instruction. For example, the higher-level controller may include a hybrid control unit (HCU), a vehicle control unit (VCU), an electric control unit (ECU), or the like.

According to an embodiment, the controller 110 may receive threshold voltage Vth for each power module 210 connected in parallel from the gate driver 120 and change the PWM signal based on the received threshold voltage Vth for each power module 210 to output the changed PWM signal to the gate driver 120.

Hereinafter, a PWM signal corresponding to an instruction will be referred to as a first PWM signal (or source PWM or reference PWM signal) and a PWM signal changed based on the threshold voltage Vth will be referred to as a second PWM signal (or changed PWM signal).

Here, the first PWM signal is generated in response to an instruction based on a preset reference count in the inverter driving apparatus 100 and may have a preset duty and amplitude for each cycle.

For example, the controller 110 may output a PWM signal for each power module 210 connected in parallel based on the threshold voltage Vth for each power module 210 connected in parallel.

The method by which the controller 110 changes the PWM signal will be described below.

The gate driver 120 may receive a PWM signal output by the controller 110 and output a control signal (or control voltage) corresponding to the PWM signal to the inverter 200.

In the present embodiment, the gate driver 120 includes a first gate driver GD1 connected to the first module group MG1 and a second gate driver GD2 connected to the second module group MG2. However, a single gate driver 120 may be connected to all power modules 210 within the inverter 200.

The gate driver 120 may monitor the threshold voltage Vth for each of the plurality of power modules 210 connected in parallel and provide the controller 110 with the threshold voltage Vth for each of the plurality of power modules 210 connected in parallel.

For example, the gate driver 120 may convert the monitored threshold voltage Vth into a digital signal to provide the digital sign to the controller 110. To this end, the gate driver 120 may include a threshold voltage monitoring circuit.

According to an embodiment, the first gate driver GD1 may include a first threshold voltage monitoring circuit 121 and monitor the threshold voltage Vth for each of the plurality of power modules 210 within the first module group MG1 connected to the first gate driver GD1 using the first threshold voltage monitoring circuit 121.

The first threshold voltage monitoring circuit 121 may monitor the threshold voltage Vth for each of the plurality of power modules 210 within the first module group MG1 connected to the first gate driver GD1 and convert the monitored threshold voltage Vth into a digital signal to provide the digital sign to the controller 110.

According to an embodiment, the second gate driver GD2 may include a second threshold voltage monitoring circuit 122 and monitor the threshold voltage Vth for each of the plurality of power modules 210 within the second module group MG2 connected to the second gate driver GD2 using the second threshold voltage monitoring circuit 122.

The second threshold voltage monitoring circuit 122 may monitor the threshold voltage Vth for each of the plurality of power modules 210 within the second module group MG2 connected to the second gate driver GD2 and convert the monitored threshold voltage Vth into a digital signal to provide the digital signal to the controller 110.

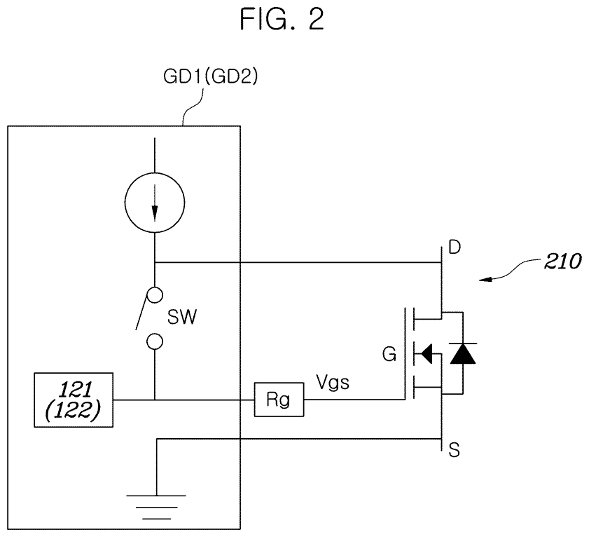

FIG. 2 is a view for describing a method of monitoring the threshold voltage Vth in an embodiment of the present disclosure.

FIG. 2 shows that the threshold voltage monitoring circuits 121, 122 may be connected to a gate terminal G of each power module 210 and monitor the voltage (gate-source voltage Vgs) between the gate terminal G and the source terminal S of the power module 210.

At this time, the threshold voltage monitoring circuits 121, 122 may monitor the gate-source voltage Vgs of the power module 210 in the state where a switching element SW connected between the gate terminal G and the drain terminal D of the power module 210 is short-circuited (i.e., the state where the gate terminal G and the drain terminal D is connected), and the gate-source voltage Vgs at this time may be the threshold voltage Vth.

A gate resistor Rg may be disposed between the threshold voltage monitoring circuits 121, 122, and any node between the gate terminal G and the source terminal S of the power module 210, and the threshold voltage monitoring circuits 121, 122 may monitor the voltage generated across the gate resistor Rg.

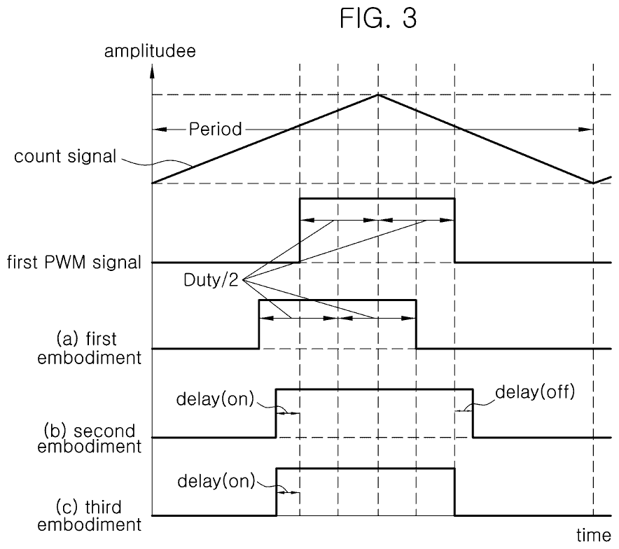

FIG. 3 is a view for describing a method by which the controller 110 changes a PWM signal in an embodiment of the present disclosure.

In FIG. 3, (a) represents the first embodiment where a turn-on delay is applied to the count to generate the second PWM signal, (b) represents the second embodiment where the turn-on delay and turn-off delay are applied to the first PWM to generate the second PWM signal, and (c) represents the third embodiment where the turn-on delay is applied to the first PWM signal to generate the second PWM signal.

FIG. 3 shows that the controller 110 according to an embodiment may change the first PWM signal (source PWM signal) based on the threshold voltage Vth for each power module 210 provided by the gate driver 120 to generate the second PWM signal (changed PWM signal) and output the changed second PWM signal to the gate driver 120.

Referring to (a) in FIG. 3, the controller 110 may apply the turn-on delay to generate the second PWM signal based on the threshold voltage Vth.

As a result, the preset count is output with a delay equal to the turn-on delay, and the first PWM signal generated according to the count is output with a delay equal to the turn-on delay.

Accordingly, the second PWM signal may be output with a delay equal to the turn-on delay, relative to the first PWM signal.

Referring to (b) in FIG. 3, the controller 110 may apply the turn-on delay to turn-on point of the first PWM signal and turn-off delay to the turn-off point of the first PWM signal based on the threshold voltage Vth to generate the second PWM signal.

As a result, the second PWM signal may have a longer duty than the first PWM signal by the turn-off delay and the turn-on delay.

Referring to (c) in FIG. 3, the controller 110 may apply the turn-on delay to the turn-on point of the first PWM signal to generate the second PWM signal based on the threshold voltage Vth.

As a result, the second PWM signal may have a longer duty than the first PWM signal by the turn-on delay.

According to an embodiment, the controller 110 may determine the delay based on the slope characteristics of the gate-source voltage Vgs of the power module 210.

For example, the controller 110 may determine the delay based on the following mathematical formula 1.

$$delay = \frac{Vth 1 - Vth 2}{dVgs / dt} ( Vth 1 > Vth 2 ) , \qquad Mathematical formula 1$$

where Vth1 is the threshold voltage of the first power module, Vth2 is the threshold voltage of the second power module, and dVgs/dt is the current flowing through the gate resistor Rg.

According to an embodiment, the controller 110 may store the delay for each Vth obtained through experiments in a table. As a result, the controller 110 may determine the delay corresponding to the received threshold voltage Vth based on the pre-stored table upon receiving the threshold voltage Vth from the gate driver 120.

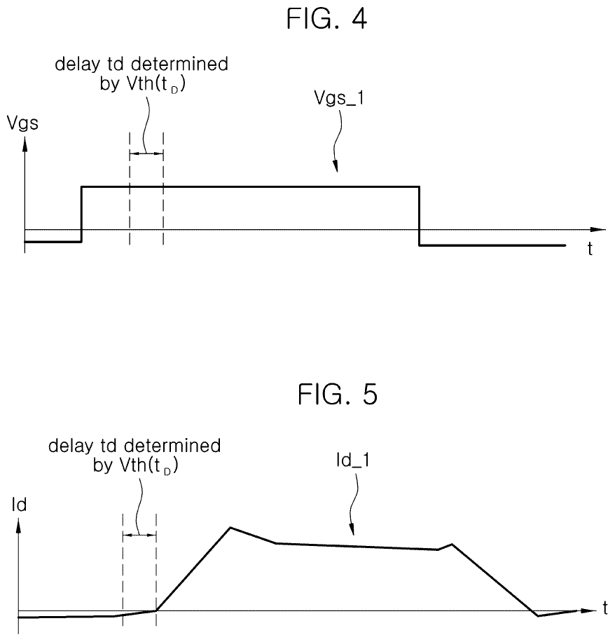

FIG. 4 is a view illustrating an example where the current Id flowing through the power module 210 is delayed by threshold voltage Vth, and FIG. 5 is a view for describing a change in the current Id flowing through the power module 210 when the PWM signal in FIG. 4 is changed in accordance with the first embodiment in FIG. 3.

FIG. 4 is a view illustrating a gate-source voltage Vgs_1 in response to a PWM signal input into a power module 210, and FIG. 5 is a view illustrating a current Id_1 flowing through a power module 210 in response to the gate-source voltage in FIG. 4.

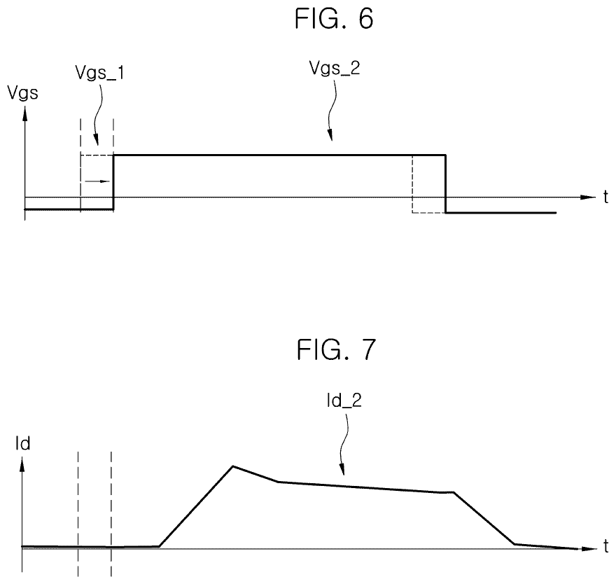

FIG. 6 is a view illustrating a gate-source voltage Vgs_2 when the PWM signal applied in FIGS. 4 and 5 is changed according to a first embodiment and input into a power module 210, and FIG. 7 is a view illustrating a current Id_2 flowing through a power module 210 in response to the gate-source voltage Vgs_2 in FIG. 6.

As illustrated in FIG. 4, the current Id_1 flowing through the power module 210 may be delayed by the time tp, which is determined by the threshold voltage Vth of the power module 210.

In contrast, the delay, which is determined by the threshold voltage Vth of the power module 210, is reflected in the generation of the PWM signal according to the embodiment of the present disclosure so that the current Id_2 may flow through the power module 210 at a preset point, as illustrated in FIG. 5.

In the embodiment of the present disclosure, changing the PWM signal is performed based on the threshold voltage Vth for each of a plurality of power modules, and each of the plurality of power modules operates according to the PWM signal in which its own threshold voltage is reflected.

Accordingly, even when the threshold voltage Vth of each of the plurality of power modules is different, the current flowing through each of the plurality of power modules flows through the power module at a preset point without any time difference so that the current imbalance may be eliminated.

On the other hand, an inverter controlling method according to an embodiment of the present disclosure may be implemented in a computer system or recorded in a recording medium. The computer system may include at least one processor, a memory, a user input device, a data communication bus, a user output device, and a storage. Each aforementioned component communicates data via a data communication bus.

The computer system may further include a network interface coupled with a network. The processor may be a central processing unit (CPU) or a semiconductor device that processes instructions stored in the memory or storage.

The memory and storage may include various types of volatile or non-volatile storage media. For example, the memory may include ROM and RAM.

Accordingly, the inverter controlling method according to an embodiment of the present disclosure may be implemented as a method executable by a computer. When the inverter controlling method according to the embodiment of the present disclosure is executed in a computer device, computer-readable instructions may execute the inverter controlling method according to the present disclosure.

On the other hand, the inverter controlling method according to the present disclosure described above may be implemented as a computer-readable code on a computer-readable recording medium. The computer-readable medium includes any type of recording medium on which data that may be decoded by a computer system is stored. For example, there may be read-only memory (ROM), random access memory (RAM), magnetic tape, magnetic disk, flash memory, optical data storage, and the like. In addition, the computer-readable recording medium may also be stored and executed as a code that may be distributed across computer systems connected via a computer network and be read in a distributed manner.

Embodiments of the present disclosure are described in greater detail with reference to the accompanying drawings, but the present disclosure is not necessarily limited to these embodiments and may be variously modified within the scope not deviating from the technical ideas of the present disclosure. Accordingly, the embodiments herein are not intended to limit but are intended to describe the technical ideas of the present disclosure, and the scope of the technical ideas of the present disclosure is not limited by these embodiments. Therefore, the embodiments described above are to be understood as illustrative non-limiting examples. The scope of protection of the present disclosure shall be construed in accordance with the scope of the claims, and all technical ideas within the scope of the claims shall be construed as falling within the scope of the rights of the present disclosure.

1. An inverter driving apparatus configured to drive an inverter including a plurality of power modules connected in parallel, the apparatus comprising:
a gate driver configured to output a control signal to the plurality of power modules and monitor a threshold voltage of each of the plurality of power modules; and
a controller configured to control the gate driver in response to an instruction input from an upper controller;
wherein the controller is configured to change a first Pulse Width Modulation (PWM) signal generated based on the instruction and based on the threshold voltage for each of the plurality of power modules provided by the gate driver to generate a second PWM signal, and to output the second PWM signal to the gate driver.

2. The apparatus of claim 1, wherein the controller is configured to change a generation point of the first PWM signal or change a duty of the first PWM signal based on a first delay determined based on the threshold voltage of each of the plurality of power modules to generate the second PWM signal.

3. The apparatus of claim 2, wherein:
the controller is configured to apply the first delay to a count serving as a reference for the generation point of the first PWM signal to generate the second PWM signal; and
the second PWM signal is generated with a second delay equal to the first delay, relative to the first PWM signal.

4. The apparatus of claim 2, wherein the controller is configured to apply the first delay to at least one of a turn-on point and a turn-off point of the first PWM signal to generate the second PWM signal having a longer duty than the first PWM signal.

5. The apparatus of claim 4, wherein:
the controller is configured to apply the first delay to the turn-on point and turn-off point of the first PWM signal; and
the turn-on point of the second PWM signal is delayed relative to the turn-on point of the first PWM signal by the first delay, and the turn-off point of the second PWM signal is delayed relative to the turn-off point of the first PWM signal by the first delay.

6. The apparatus of claim 4, wherein:
the controller is configured to apply the first delay to the turn-on point of the first PWM signal; and
the turn-on point of the second PWM signal is delayed relative to the turn-on point of the first PWM signal by the first delay.

7. The apparatus of claim 1, wherein the controller is configured to determine the first delay based on slope characteristics of a gate-source voltage of the plurality of power modules.

8. The apparatus of claim 7, wherein the controller is configured to determine the first delay based on:
$$delay = \frac{Vth 1 - Vth 2}{dVgs / dt} ( Vth 1 > Vth 2 ) ,$$
where Vth1 is a threshold voltage of a first power module, Vth2 is a threshold voltage of a second power module, and dVgs/dt is current flowing through a gate resistor Rg.

9. The apparatus of claim 1, wherein the controller is configured to determine the first delay corresponding to a threshold voltage based on a table including delays for each threshold voltage of each of the plurality of power modules.

10. The apparatus of claim 1, wherein the gate driver includes a threshold voltage monitoring circuit configured to monitor the threshold voltages of the plurality of power modules, to convert the monitored threshold voltages into digital signals, and to provide the digital signals to the controller.

11. The apparatus of claim 1, wherein:
the inverter includes a plurality of module groups including a plurality of power modules connected in parallel;
the gate driver is connected to each of the plurality of module groups; and
the gate driver is configured to monitor the threshold voltages for the plurality of power modules within the plurality of module groups.

12. The apparatus of claim 1, wherein the gate driver is configured to monitor the voltage of a gate resistor connected between the gate driver and a gate terminal of the power module in a state where a switch element connected between the gate terminal and a drain terminal of the power module is short-circuited.

13. A method of controlling an inverter including a plurality of power modules connected in parallel, the method comprising:
generating, by a controller, a first Pulse Width Modulation (PWM) signal in response to an instruction input from an upper controller, and outputting the first PWM signal to a gate driver;
monitoring, by the gate driver, a threshold voltage of each of the plurality of power modules;
providing, by the gate driver, the monitored threshold voltages to the controller; and
changing, by the controller, the first PWM signal to generate a second PWM signal based on the threshold voltages, and outputting the second PWM signal to the gate driver.

14. The method of claim 13, further comprising changing, by the controller, a generation point of the first PWM signal or change a duty of the first PWM signal based on a first delay determined based on the threshold voltage of each of the plurality of power modules to generate the second PWM signal.

15. The method of claim 14, further comprising applying, by the controller, the first delay to a count serving as a reference for the generation point of the first PWM signal to generate the second PWM signal; and
generating the second PWM signal with a second delay equal to the first delay, relative to the first PWM signal.

16. The method of claim 14, further comprising applying, by the controller, the first delay to at least one of a turn-on point and a turn-off point of the first PWM signal to generate the second PWM signal having a longer duty than the first PWM signal.

17. The method of claim 16, further comprising applying, by the controller, the first delay to the turn-on point and turn-off point of the first PWM signal;
wherein the turn-on point of the second PWM signal is delayed relative to the turn-on point of the first PWM signal by the first delay, and the turn-off point of the second PWM signal is delayed relative to the turn-off point of the first PWM signal by the first delay.

18. The method of claim 16, further comprising applying, by the controller, the first delay to the turn-on point of the first PWM signal, wherein the turn-on point of the second PWM signal is delayed relative to the turn-on point of the first PWM signal by the first delay.

19. A vehicle comprising an inverter including a plurality of power modules connected in parallel, and an inverter driving apparatus for controlling the inverter, wherein the inverter driving apparatus comprises:
a gate driver configured to output a control signal to the plurality of power modules, and to monitor threshold voltages of the plurality of power modules; and
a controller configured to control the gate driver in response to an instruction input from an upper controller;
wherein the controller is configured to change a first Pulse Width Modulation (PWM) signal generated in response to the instruction to generate a second PWM signal based on the threshold voltages for the plurality of power modules provided by the gate driver, and to output the second PWM signal to the gate driver.

20. The vehicle of claim 19, wherein the controller is configured to change a generation point of the first PWM signal or change a duty of the first PWM signal based on a first delay determined based on the threshold voltages of the plurality of power modules to generate the second PWM signal.
